(19) United States
(12) Patent Application Publication
(10) Pub. No.: US 2025/0071926 A1
(43) Pub. Date: Feb. 27, 2025

(54) MULTI-URL SEAT FOR ELECTRICAL ENCLOSURE

(71) Applicant: LATELEC, Toulouse (FR)

(72) Inventors: Bastien PUERTOLAS, Aigrefeuille Occitanie (FR); Thierry CURMI, Brax (FR)

(73) Assignee: LATELEC, Toulouse (FR)

(21) Appl. No.: 18/717,478

(22) PCT Filed: Dec. 5, 2022
(86) PCT No.: PCT/EP2022/084372

§ 371 Date: Jun. 7, 2024

(30) Foreign Application Priority Data
Dec. 9, 2021 (FR) FR2113233

(51) Int. Cl. H05K 7/14

(52) U.S. Cl. CPC H05K 7/1412

(57) ABSTRACT

A multi-LRU tray (1) of an electrical enclosure having a base (2), a backrest (3), two lateral brackets (4) to house at least two LRU (10) inserted along at least one of the transverse guiding ramps (2a) and an interconnection system (5) to electrically connect the LRU (10). The backrest (3) has at least one opening per LRU (10), through which an interconnection system (5) incorporating a printed circuit board (5c) is fitted.

### CROSS REFERENCE TO RELATED APPLICATION

This application is a national stage entry of PCT/EP2022/084372 filed Dec. 5, 2022, under the International Convention and claiming priority over French Patent Application No. FR2113233 filed Dec. 9, 2019.

### TECHNICAL FIELD

The invention relates to a tray of electrical enclosures, used notably in the aeronautical field. These enclosures are composed of shelves for accommodating housings containing electrical and/or electronic source processing and/or control signal processing equipment items which implement the operation of a given entity. These housings take the form of elements of standardized interchangeable sizes and conventionally called LRU—acronym for “Line Replaceable Unit”—when they are provided with such equipment items, each of these LRUs being installed on a support called a tray. Notably, the vehicles—aircraft, trains, ships—and the buildings are intended to be entities equipped with such enclosures.

In the aeronautical field, these enclosures, called avionics racks, are of large size because many equipment items, such as the flight instruments, contribute to the operation of the aircraft. These avionics racks arrange the trays, one per LRU, which ensure the organization, the connection and the cooling of the corresponding LRUs.

The tray has a multiple-interface role: first of all it provides a mechanical interface because it supports and locks the LRU which is installed thereon. It also provides an electrical interface by connecting each LRU to at least one equipment item of the aircraft and/or to other LRUs. And finally, it adds a thermal interface between the coolant and the LRU in order to control the temperature thereof. Indeed, these LRUs, by the electrical nature of their content, produce heat which has to be discharged in order to maintain optimum operation.

### STATE OF THE ART

In the aeronautical structures, the LRU trays, primarily of ARINC type, are conventionally installed on the shelves of the avionics racks, each tray then being able to accommodate and lock only a single LRU by rear connection. Different ARINC formats are available and allow chosing a tray matching the dimensions of each LRU to be installed in the avionics racks.

Each of these LRUs contains at least one electrical and/or electronic equipment item which needs to be connected to and powered by electrical cables. These LRUs also make it possible to control additional equipment items outside of the racks which are necessary to the operation of the aircraft: additional electrical links are therefore required to provide these control functions. Furthermore, the expansion of digital technology increases the quantity of transiting data to be processed and consequently multiplies the information exchange channels, which leads to another increase in the number of electrical links connected to these LRUs, also called modules in the state-of-the-art.

Because the connections of the LRUs are made blind on their rear face, modifying the bundles of cables when changing an LRU is then complex to implement.

The patent FR3083048 improves the connection of racks through the use of an interconnection system comprising a printed circuit board of so-called “flex-rigid” structure, comprising rigid parts facing the rear face of each rack alternating with flexible parts linking two consecutive rigid parts. These flexible parts give a flexibility to the interconnection system, allowing it to adapt to the random and relative movements of each rack, provoked for example by vibrations. However, the flexible parts are difficult to produce because they must contain all of the cables linking the modules, the latter being linked in series. They are more fragile and only moderately withstand the relative movements of two adjacent modules.

Furthermore, the patent FR3097403 attempts to partially resolve the issue of the flexible parts by connecting each rigid part in parallel on an interconnection plate: the flexible parts are therefore no longer dependent on the relative movements between two modules. However, the production difficulties render its use also problematical.

Other trays of IMA (acronym for “Integrated Modular Avionics”) and IMA2G (IMA second generation) rack type constitute independent structures of the avionics racks and structures which host a set of modules—LRMs (acronym for “Line Replaceable Modules”)—interconnected by a printed circuit board on their rear face. These trays of IMA and IMA2G racks are of reduced size and form a cabinet assembly equivalent to a single shelf. They can therefore be installed more easily in the cabin of the aircraft outside of the avionics racks to correspond for example to a local computer requirement. An IMA rack tray can house a multitude of modules intended to work in parallel. However, this multi-module IMA cabinet assembly corresponds to an LRU and the integration thereof in an avionics rack would be equivalent to installing a cabinet assembly in a cabinet assembly.

### SUMMARY OF THE INVENTION

In order to remedy the drawbacks of the state-of-the-art set out hereinabove, the main objective of the invention is to improve the production of the avionics racks that use modules of ARINC type by allowing a simplification of the wirings, and a time saving on installing the trays.

For this, the invention relates to a tray of ARINC type with a structure that is suitable for housing several LRUs juxtaposed, by occupying a part or all of an avionics rack shelf. This tray also provides the complete rear face connection system of each of the LRUs that it includes.

More specifically, the subject of the present invention is a multi-LRU tray of an electrical enclosure comprising a base defining a given reference plane, a backrest extending in a plane at right angles to the base, and two lateral brackets at right angles to the base and to the backrest. The base is drilled with ventilation holes and has at least one transverse guiding ramp extending at right angles to the backrest and at least one locking mechanism. The multi-LRU tray can house at least two LRUs connected to equipment items external to and/or contained in other LRUs. Each LRU is inserted along at least one of the transverse guiding ramps and held in position by at least one of the locking mechanisms. In addition, the backrest has at least one opening per LRU, through which an LRU interconnection system is fitted.

The tray is said to be multi-LRU because it is intended to house within its structure a plurality of LRUs. The incorporation of this multi-LRU tray is performed in the same way as the incorporation of a conventional single-LRU tray. Advantageously, this incorporation is done more rapidly and more easily because of a lesser number of drill-holes and of fixings, and this is so regardless of the configuration of the LRUs housed on the multi-LRU tray. Indeed, in the case of single-LRU trays, each incorporation of a tray in an enclosure shelf, for example on an avionics rack, is ordered and dependent on the LRU which will be connected to it.

Furthermore, once incorporated, the multi-LRU tray can directly accommodate several LRUs, which constitutes a time saving proportional to the number of LRUs that it accommodates. A weight saving is also obtained due to the reduction of the number of components and of the quantity of material constituting the mechanical assembly of the multi-LRU tray, compared to the sum of multi-LRU trays accommodating the same number of LRUs, in particular because of the number of brackets required.

This multi-LRU structure, in particular the base of the tray produced in a single piece, also reduces the problem of air leakage observed between two single-LRU trays: indeed, a structural play between neighbouring single-LRU trays provokes ventilation leaks of the coolant from the electrical enclosure. Now the one-piece base of the multi-LRU tray improves the circulation of the ventilation and the cooling of the LRUs that it accommodates by having a better cooling efficiency. This improved efficiency is accompanied by a reduction of the energy consumption necessary to this cooling, an effect that is particularly sought after in all applications of this type.

Furthermore, the independent interconnection system makes it possible to conduct tests and electrical inspections before the final mounting of the modules, and to simplify if necessary any repairs in the case of observed faults. Furthermore, this independent interconnection system can advantageously be prepared before it is finally incorporated on the tray, providing a time saving in the installation of the enclosure and an optimization of production.

This independence also makes it possible to change the wiring of the multi-LRU tray by the addition or the modification of the electrical links by replacing only the interconnection system while retaining the same multi-LRU tray.

According to certain preferred embodiments:
the interconnection system incorporates a printed circuit board;
The interconnection system comprises at least one output plug and at least one support block producing a spacer fixed to an output plug of the multi-LRU tray and to a front face of the printed circuit board;
the interconnection system comprises a protection closure plate on a rear face of the printed circuit board;
the support blocks can be secured to and form a housing covering the front face of the printed circuit board;
a set of main fixings secures to the backrest each corresponding output plug to transfer the efforts from the LRU to the backrest;
a secondary set of fixings secures the printed circuit board to the support blocks and to the output plugs;
a tertiary set of fixings holds together the support blocks, the printed circuit board and, optionally, the closure plate of the interconnection system;
the sets of fixings are of screw and/or screw-nut type, or equivalent types;
the output plugs are coupled to a PGA (acronym for “Pin Grid Array”) on the printed circuit board, and
tray output connectors are arranged on the rear face of the printed circuit board.

Advantageously, the printed circuit board at the core of the interconnection system makes it possible to assemble together, on a single support, electrical links. This compact solution provides savings by reducing the bulk and the suspended weights of the wiring zones at the rear of the electrical enclosures for the interconnection. The LRUs can therefore be installed by reducing their front overhang, thus enhancing the structural withstand strength of the electrical enclosure.

Also advantageously, the support blocks ensure that the printed circuit board is held on the multi-LRU tray by the secondary set of fixings. Indeed, the printed circuit board is not then secured directly to the LRUs and is thus protected from the relative movements of these LRUs: the efforts deriving from these movements are transferred by the main set of fixings and absorbed only by the backrest of the multi-LRU tray.

Also advantageously, the use of the PGAs allows for an optimized ability to dismantle the ports to replace those which might be damaged. The directly matched dimensions of the support blocks guarantee the good coupling of the ports on the PGAs.

### DESCRIPTION OF THE FIGURES

Other features and advantages of the present invention will emerge on reading the following exemplary detailed embodiment without limiting the scope thereof, with reference to the attached figures which represent, respectively:

FIG. 1, a perspective view of an exemplary multi-LRU tray according to the invention;

FIG. 2, an exploded view of the top of the multi-LRU tray of FIG. 1;

FIG. 2a, a local enlargement of FIG. 2 showing the connection between the printed circuit board and LRUs via PGA taps;

FIG. 3, an exploded side view of the multi-LRU tray according to the preceding figures;

FIG. 4, an exploded front-end view of the interconnection system of this multi-LRU tray;

FIG. 5, a front-end view of the interconnection system of FIG. 4;

FIG. 6 and FIG. 7, rear views of the interconnection system respectively without and with closure plate.

### DETAILED DESCRIPTION

In the figures, identical reference symbols refer to a same element and to the corresponding passages of the description.

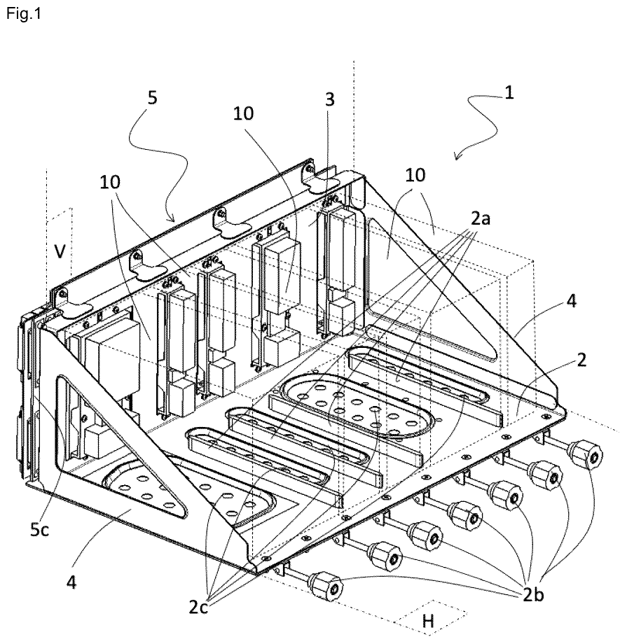

FIG. 1 illustrates in perspective an exemplary multi-LRU tray 1 according to the invention housing five LRUs 10, seen transparently to allow all of the elements represented to be seen. This multi-LRU tray 1 is provided to be installed in an electrical cabinet assembly, on a shelf of an electrical enclosure of an aircraft in this example. These LRUs 10 are connected to equipment items either external to the electrical enclosure or contained in other LRUs.

This multi-LRU tray 1 is composed of a base 2 defining a reference plane H, a backrest 3 extending in a plane V at right angles to the base 2, and two lateral brackets 4 extending in planes at right angles to the base 2 and to the backrest 3. The LRUs 10 are disposed juxtaposed on the base 2 and positioned between the lateral brackets 4. They are connected electrically by the interconnection system 5 installed on the backrest 3.

The base 2 has five transverse guiding ramps 2a extending at right angles to the backrest 3 and seven locking mechanisms 2b. Each LRU 10 is inserted along two transverse guiding ramps 2a, except for the LRUs at the end of juxtaposition, one of which in this example is inserted between a ramp 2a and a lateral bracket 4. The number of locking mechanisms 2b necessary to, alternately, lock and release each LRU in position depends on the size of the LRU: in this exemplary embodiment, two LRUs 10 are held in position by two locking mechanisms 2b and the three other LRUs by just one.

The base 2 is also drilled with ventilation holes 2c located in groups under each LRU 10. The number of holes depends on the size of the LRU concerned: the greater the dimensions of the LRU, the greater the number of ventilation holes 2c.

The backrest 3 has one opening per LRU 10, these openings making it possible to fit the interconnection system 5 of the LRUs 10 to the equipment items that are external to and/or contained in other LRUs, this system incorporating a rigid printed circuit board 5c.

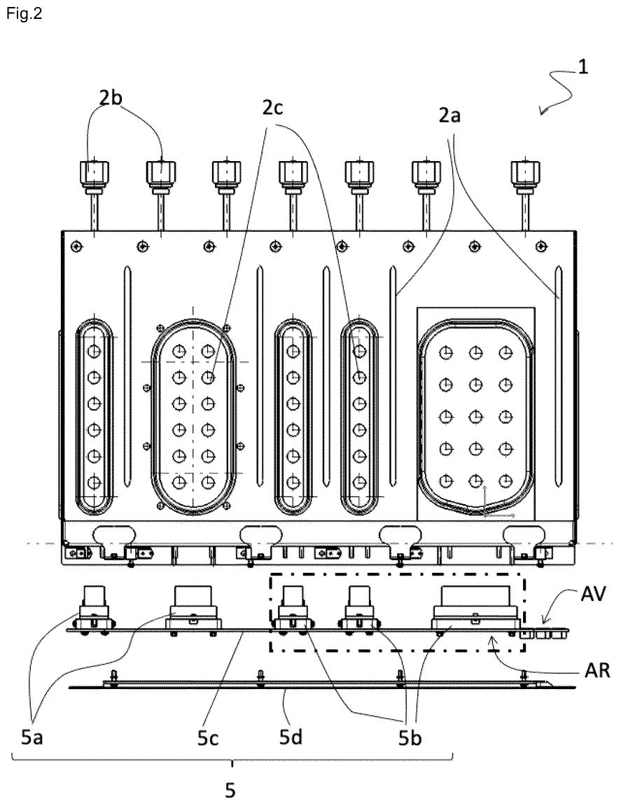

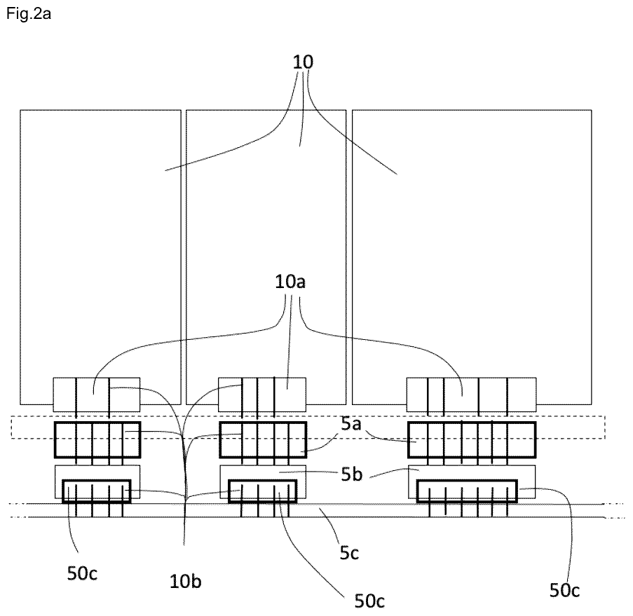

The interconnection system 5 is detailed in FIGS. 2 to 4, in particular FIG. 2 shows an exploded view of the top of the multi-LRU tray 1 with the interconnection system 5 not yet installed on the tray in this example. This system comprises output plugs 5A, support blocks 5b and—advantageously—a closure plate 5d on the rear face AR of the printed circuit board 5c. Such a closure plate 5d makes it possible to protect the printed circuit board 5c, in particular mechanically through its rigid structure and electrically or electromagnetically through the presence of an insulating covering made of a material known to obtain this effect. The closure plate 5d can advantageously protect the printed circuit board 5c from any surrounding pollution element (water, dust, etc.).

Each support block 5b produces a spacer fixed to an output plug 5a of the multi-LRU tray 1 and to the front face AV of the printed circuit board 5c. In this exemplary embodiment, the support blocks 5b are independent of one another. Alternatively, they can be secured together and overall form a housing covering the front face AV of the printed circuit board.

The output plugs 5a are electrically connected with the connecting ports 10a of the LRUs 10. In this exemplary embodiment, illustrated in particular by FIG. 2a which is a local enlargement of FIG. 2, the connecting ports 10A, the output plugs 5a and the connections 50c of the printed circuit board 5c produce electrical links. These links have arrays of micro-pins 10b which are mutually plugged together to produce the connections. The connections 50c each constitute a PGA (Pin Grid Array) to which the output plugs 5a are coupled, these connections 50c being soldered or connected by press-fit system to the printed circuit board 5c.

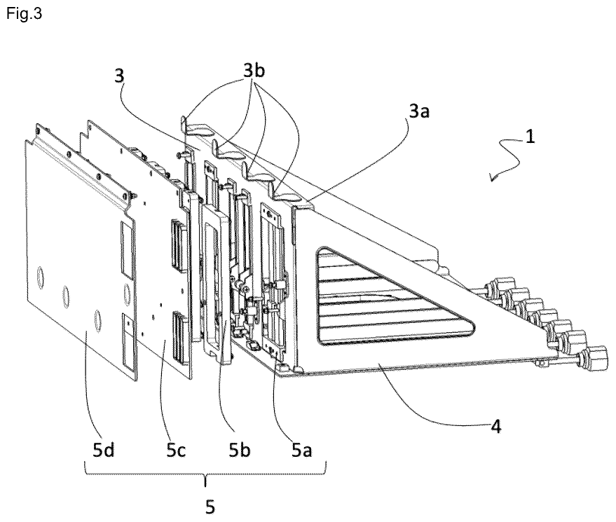

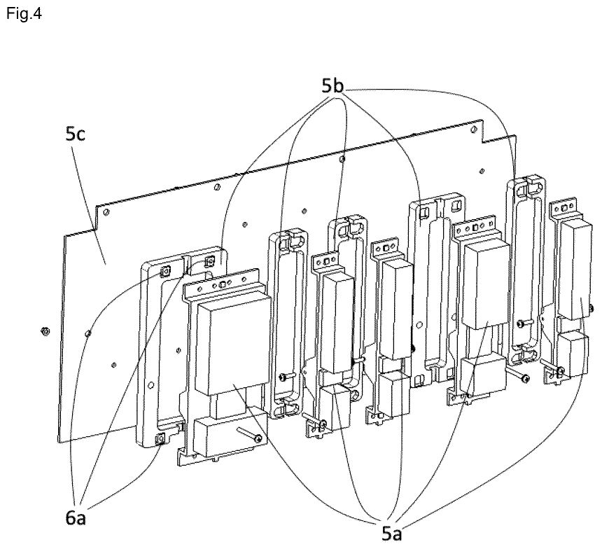

FIG. 3 and FIG. 4 show exploded views, respectively lateral and front-end, of the multi-LRU tray 1 and of the stacking of the constituent elements of the interconnection system 5, illustrating in particular the output plugs 5A, the support blocks 5b, the printed circuit board 5c and the protection closure plate 5d. In this exemplary embodiment, the backrest 3 comprises a top angle iron 3a on which are installed four corner supports 3b. These corner supports 3b make it possible to adjust the fixing of the interconnection system 5 to the backrest 3 of the multi-LRU tray 1.

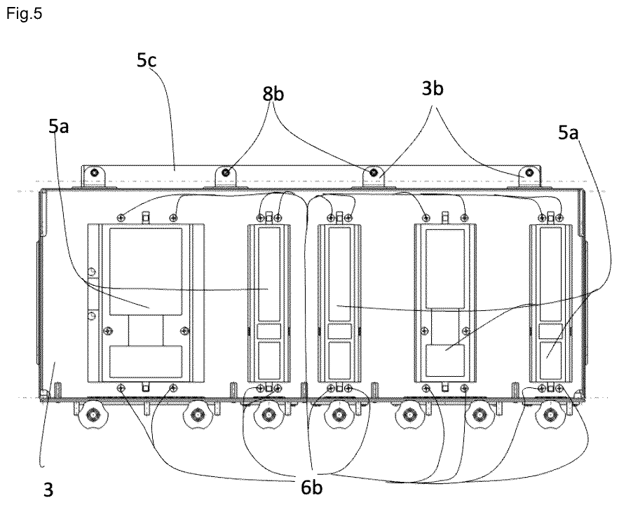

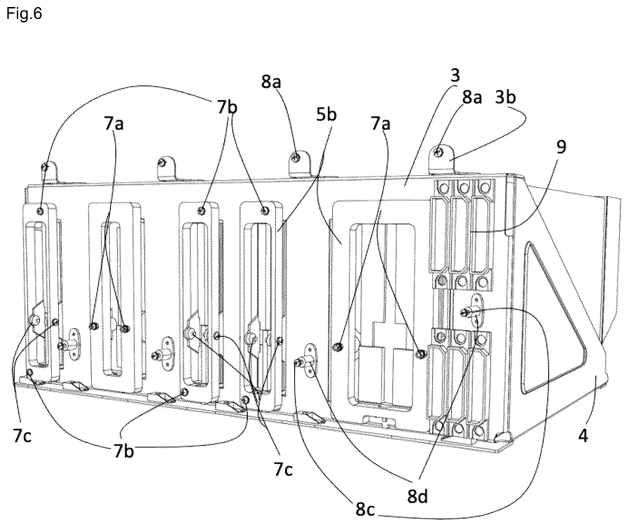

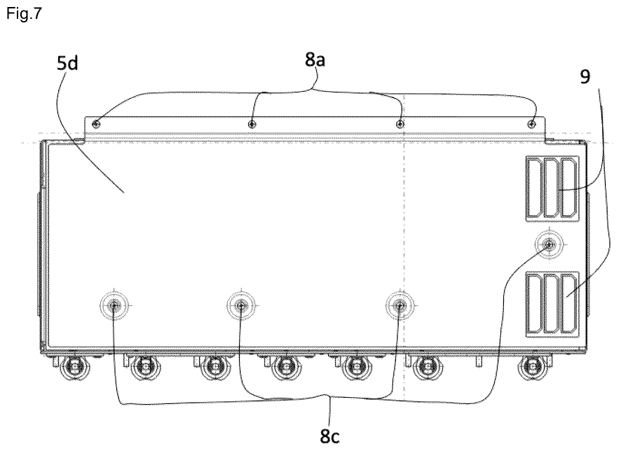

Three main, secondary and tertiary sets of fixings are used to assemble the interconnection system 5 with the backrest 3 and are represented respectively in FIG. 5, FIG. 6 and FIG. 7. According to FIG. 5, the main set of fixings secures the backrest 3 with the corresponding output plug 5a to transfer the efforts from the LRU to the backrest 3, these efforts originating from the relative movements of each LRU during the movements and the flights of the aircraft which generate vibrations and jerks. This direct link by a screw 6b-nut 6a assembly—of which the nut 6a is free with play in the support block 5b—makes it possible, by this transfer of efforts from the LRU 10 to the backrest 3, to protect the printed circuit board 5c from these efforts. The four screws 6b of the screw-nut assembly are disposed in pairs at the ends of each support block 5b in a vertical direction in the plane V of the backrest 3.

Screws 7a, 7b and 7c of the secondary set of fixings, illustrated by the rear view of FIG. 6, secure the printed circuit board 5c to the support blocks 5b and to the output plugs 5a. This securing can be direct or combined depending on the size of the support block 5b. In the case where the support block 5b is sufficiently wide, each screw 7a of the secondary set of fixings assembles the printed circuit board 5c with a support block 5b and the corresponding output plug 5a in a median zone of the support block 5b. Otherwise, two screws 7b and two screws 7c are used and respectively assemble the printed circuit board 5c with a support block 5b on the one hand and the support block 5b with the output plug 5a on the other hand, the screws 7b being oriented in the same direction as the screws 6b and the screws 7c being at right angles to the screws 7b.

The tertiary set of fixings, illustrated by the rear view of FIG. 7, hold together the support blocks 5b, the printed circuit board 5c and the closure plate 5d of the interconnection system 5 and is composed of two rows of screws. The top row links, by four screws 8a and four nuts 8b, the closure plate 5d with the printed circuit board 5c and the corner supports 3b. The bottom row secures, by four screws 8c, the closure plate 5d with the printed circuit board 5c on spacer columns 8d fixed to the backrest 3. These spacer columns 8d are visible in FIG. 6.

The closure plate 5d has two openings making it possible to disengage the output connectors 9 of the multi-LRU tray 1 arranged on the rear face AR of the printed circuit board 5c in this exemplary embodiment. These multi-LRU tray 1 output connectors 9 produce the connections of the multi-LRU tray 1 to the other equipment items of the enclosure and/or of the aircraft.

According to other embodiments, any type of printed circuit board other than rigid can be used, such as multi-layer circuits, rigid/flexible circuits. Also, the sets of fixings use screws and screw-nut systems: other types of fixings, rivets and clips for example, make it possible to maintain the assembly of the interconnection system. In addition, depending on the arrangement of the multi-LRU tray and of the electrical enclosure, the tray output connectors are also able to be positioned on the front face of the printed circuit board. Furthermore, a conventional wiring can be used instead of a printed circuit board.

The multi-LRU tray backrest is flat and the assembly of the interconnection system is adjusted by the angle iron of the backrest and the corner supports in the example illustrated: an alternative can use a stamped backrest that makes it possible to arrange the printed circuit board and the support blocks and to directly fix the closure plate to the backrest.

This multi-LRU tray is not limited to electrical enclosures: any cabinet assembly comprising LRUs of ARINC type, such as the galleys of commercial airplanes, can be equipped with a multi-LRU tray.

1. A multi-LRU tray (1) of an electrical enclosure comprising:
a base (2) defining a given reference plane (H),
a backrest (3) extending in a plane (V) at right angles to the base (2), and
two lateral brackets (4) at right angles to the base (2) and to the backrest (3), the base (2) being drilled with ventilation holes (2c) and having at least one transverse guiding ramp (2a) extending at right angles to the backrest (3) and at least one locking mechanism (2b),
wherein the multi-LRU tray (1) houses at least two LRUs connected to equipment items external to and/or contained in other LRUs, each LRU being inserted along at least one of the transverse guiding ramps (2a) and held in position by at least one of the locking mechanisms (2b), and the backrest (3) having at least one opening per LRU through which an interconnection system (5) of the LRUs (10) incorporating a printed circuit board (5c) is fitted.

2. The multi-LRU tray (1) as claimed in claim 1, wherein the interconnection system (5) comprises at least one output plug (5a) and at least one support block (5b) producing a spacer fixed to an output plug (5a) of the multi-LRU tray (1) and to a front face (AV) of the printed circuit board (5c).

3. The multi-LRU tray (1) as claimed in claim 2, wherein the interconnection system (5) comprises a protection closure plate (5d) on a rear face (AR) of the printed circuit board (5c).

4. The multi-LRU tray (1) as claimed in claim 2, wherein the support blocks (5b) are secured and form a housing covering the front face of the printed circuit board (5c).

5. The multi-LRU tray (1) as claimed in claim 2, wherein a main set of fixings secures to the backrest (3) each corresponding output plug (5a) to transfer the efforts from an LRU to the backrest (3).

6. The multi-LRU tray (1) as claimed in claim 2, wherein a secondary set of fixings secures the printed circuit board (5c) to the support blocks (5b) and to the output plugs (5a).

7. The multi-LRU tray (1) as claimed in claim 2, wherein a tertiary set of fixings (8) hold together the support blocks (5b) and the printed circuit board (5c) of the interconnection system (5).

8. The multi-LRU tray (1) as claimed in claim 7, wherein the tertiary set of fixings (8) hold together the support blocks (5b), the printed circuit board (5c) and thea closure plate (5d) of the interconnection system (5).

9. The multi-LRU tray (1) as claimed in claim 5, wherein at least one set of fixings is of screw and/or screw-nut type.

10. The multi-LRU tray (1) as claimed in claim 2, wherein the output plugs (5a) are coupled to an array of pins on the printed circuit board (5c).

11. The multi-LRU tray (1) as claimed in claim 3, wherein multi-LRU tray (1) output connectors (9) are arranged on the rear face (AR) of the printed circuit board (5c).
